(19) United States
(12) Patent Application Publication
(10) Pub. No.: US 2026/0116739 A1
(43) Pub. Date: Apr. 30, 2026

(54) MICROELECTROMECHANICAL COMPONENT AND MICROELECTROMECHANICAL INERTIAL SENSOR

(71) Applicant: Robert Bosch GmbH, Stuttgart (DE)

(72) Inventors: Andrea Opreni, Reutlingen (DE); Daniel Baumgaertner, Budapest (HU); Maria Cruz Varona, Stuttgart (DE); Rolf Scheben, Reutlingen (DE); Stefan Kiesel, Reutlingen (DE)

(21) Appl. No.: 19/352,192

(22) Filed: Oct. 7, 2025

(30) Foreign Application Priority Data
Oct. 25, 2024 (DE) 10 2024 210 301.2

(51) Int. Cl. B81B 3/00

(52) U.S. Cl. CPC B81B 3/0072; B81B 2201/0235; B81B 2201/0242; B81B 2203/0118; B81B 2203/0163; B81B 2203/0307; B81B 2207/01

(57) ABSTRACT

A microelectromechanical component. The microelectromechanical component includes a substrate with a substrate surface, a mass that is movable relative to the substrate surface, and a stop spring arranged between the substrate and the movable mass, wherein the stop spring extends from a mechanical anchor in a cantilevered manner parallel to the substrate surface, and wherein the stop spring has a decreasing width along its longitudinal extension from the mechanical anchor to a free end of the stop spring. A microelectromechanical inertial sensor having such a microelectromechanical component, is also described.

### FIELD

The present invention relates to a microelectromechanical component and to a microelectromechanical inertial sensor comprising such a microelectromechanical component.

### BACKGROUND INFORMATION Certain microelectromechanical components and inertial sensors are described in the related art. Microelectromechanical systems are also referred to abbreviated as MEMS.

Germany Patent Application No. DE 10 2020 204 767 A1 describes a micromechanical device with a substrate, a movable mass and a stop spring structure, the stop spring structure having different spring constants depending on the spatial direction.

### SUMMARY

According to an example embodiment of the present invention, a microelectromechanical component is provided which comprises a substrate with a substrate surface, a mass that is movable relative to the substrate surface, and a stop spring arranged between the substrate and the movable mass, the stop spring extending from a mechanical anchor in a cantilevered manner parallel to the substrate surface, and the stop spring having a decreasing width along its longitudinal extension from the mechanical anchor to a free end of the stop spring.

In simple terms, a comparatively widely anchored stop spring with a spring shape that tapers along its cantilevered extension is used in order to allow for an improved stop function of the stop spring. With a spring shape that becomes increasingly narrower towards the free end of the stop spring, a stop spring is provided that is mechanically particularly robust and significantly less susceptible to adhesion to the movable mass or to the substrate. The special spring shape with a width decreasing towards the free end allows for improved suppression of higher oscillation modes and reduced susceptibility to mechanical stress through a structural reduction of eigenmodes of the stop spring and a shift of the center of mass towards the mechanical anchor so that the stop spring has increased vibration and shock resistance. As a result, the microelectromechanical component can be better protected overall against mechanical overload and operated in a mechanically reliably controlled manner. The proposed design of the stop spring also allows for a compact design of the microelectromechanical component.

Microelectromechanical components are subject to high demands with regard to their mechanical robustness and reliable usability, in particular due to their microstructural design. In the case of microelectromechanical components with movable masses, it is not only the lowest possible shock sensitivity that is relevant, but rather contact between the movable mass or a stop spring that intercepts the movable mass, and adjacent component structures, can lead to mechanical adhesion effects, which can be amplified by electrostatic effects and can impair the functionality of the microelectromechanical component. In practice, the aim is therefore to design the component elements of microelectromechanical components in such a way that such adhesion effects can be avoided or at least their effects can be reduced. With the microelectromechanical component according to the features of the present invention, the adhesion behavior and the mechanical resistance of the microelectromechanical component can advantageously be optimized. Adhesion is considered to be a temporary or permanent contact between movable and immovable structures of the microelectromechanical component due to mechanical and electromechanical interactions and attractive forces. Mechanical resistance is understood to be a property of the microelectromechanical component to withstand shocks and repeated impacts without damage, in particular without breakage or chipping.

In principle, a microelectromechanical component can, for example, be a component that is produced with semiconductor technology and has mechanical and electrical microstructures. A microelectromechanical component can be suitable for implementation as a system-on-chip (SoC) due to its microstructural design. Microelectromechanical components can be used, for example, as miniaturized sensors or actuators. Microelectromechanical components can, for example, be manufactured by a successive arrangement and structuring of material layers and thus be present in a layer structure. The material layers can be produced successively on the substrate.

The material layers can in particular be silicon-based, for example formed from monocrystalline or polycrystalline silicon layers, which can be doped or undoped as required. Free spaces in the microelectromechanical component can be created in particular by selective etching processes in the layer structure. The microelectromechanical component according to the proposed features can be easily manufactured using common semiconductor technology processes without the need for complex adaptations, for example to implement the described stop spring.

A substrate can be a flat semiconductor carrier structure. The substrate can be a silicon wafer, for example. The substrate has two mutually opposing substrate surfaces that are present on a front side and a rear side of the substrate. The front side of the substrate can form an active side of the substrate, on which side the mechanical and electrical microstructures of the microelectromechanical component are arranged. The substrate surface regularly referred to below can refer in particular to the substrate surface on the front side of the substrate.

A mass that is movable relative to the substrate surface can be a microstructural element of the microelectromechanical component that is deflectable in at least one predefined spatial direction. Depending on the design, the movable mass can be deflected, for example, perpendicularly and/or parallel to the substrate surface. The movable mass can, for example, be movably connected to a fixed frame and/or to the substrate of the microelectromechanical component via a spring structure. The movable mass can, for example, be designed as a seismic mass if the microelectromechanical component is designed as a sensor component, in particular as an inertial sensor component. A seismic mass can be a mechanical inertial body for interacting with a translational or rotational acceleration force acting on the microelectromechanical component. The seismic mass can be configured in particular to detect accelerations perpendicular to the substrate surface. Depending on the acceleration force to be detected and the measurement principle used, the seismic mass can, for example, be designed as a rocker structure with rocker arms that have an asymmetric mass distribution and are pivotable about a torsion spring axis; it can be designed as a trampoline structure with a translational displaceability of the entire seismic mass, or it can be configured as an oscillating rotor for rotation rate detection.

A stop spring can be a microstructural element of the microelectromechanical component which is resiliently deflectable in at least one predefined spatial direction and is configured to absorb mechanical impact energy of a component element striking the stop spring, in particular the movable mass striking the stop spring or the substrate striking the stop spring. Due to the resilient spring properties of the stop spring, it can also exert a restoring force on a component element that strikes the stop spring. Especially in microelectromechanical sensor components designed as inertial sensor components, stop springs represent an important mechanical protective element as flexible stoppers for the seismic mass. They serve as the resilient first contact point of the seismic mass in the case of accelerations that exceed a predefined acceleration threshold value for acceleration detection, and thus avoid mechanical overload on the microelectromechanical component structures. The stop spring can reduce the acting impact forces by absorbing a portion of the impact energy and can convert the impact energy into elastic deformation energy to avoid pronounced local stress peaks, thus increasing the mechanical resistance of the microelectromechanical component. Due to its special spring shape, the stop spring can have a lower spring stiffness along its height extension than perpendicular thereto along its length and width extensions.

The stop spring has a mechanical anchor. With the mechanical anchor, the stop spring is, for example, firmly connected to the movable mass or to the substrate and fixed in place in the microelectromechanical component. The mechanical anchor can, for example, be a semiconductor element which is structured from a semiconductor layer and, depending on the design, can connect the substrate or the movable mass to the stop spring. Starting from the mechanical anchor, the stop spring extends in a cantilevered manner, i.e., in particular without further mechanical support on a component element of the microelectromechanical component, to a free end of the stop spring. The free end of the stop spring is located at an end of the stop spring opposite the mechanical anchor with respect to the longitudinal extension of the stop spring. In particular, the free end of the stop spring is not mechanically fixed, but rather positioned in a free space between the substrate and the movable mass. In particular, it is not absolutely necessary to arrange the movable mass on the stop spring if there is a mechanical interaction between the movable mass and the stop spring. This allows, for example, a seismic mass of a z-acceleration sensor to be designed more eccentrically, which contributes to an improvement in offset stability and a reduction in the noise of the microelectromechanical component.

The stop spring extends substantially parallel to the substrate surface, such a parallel extension being related in particular to an unloaded rest state of the stop spring. When a component structure such as the movable mass or the substrate strikes the stop spring, the stop spring can have an at least partially inclined and/or curved course with respect to the substrate surface. The stop spring has a longitudinal extension, a width extension and a height extension. The longitudinal extension and the width extension can each refer to an extent of the stop spring parallel to the substrate surface. The height extension can refer to an extent of the stop spring perpendicular to the substrate surface. The height extension can be several times smaller than the longitudinal extension and the width extension so that a substantially flat stop spring is present. The contours of the stop spring along its longitudinal extension and its width extension can define a two-dimensional basic shape of the stop spring, for which advantageous embodiments are described below. The longitudinal extension of the stop spring can be defined by a straight line of the stop spring between the mechanical anchor and its free end and can be viewed, for example, along a central longitudinal axis of the stop spring. The width extension runs perpendicularly to the longitudinal extension. A width decreasing along the longitudinal extension is understood to mean, for example, a stepwise or continuously decreasing width extension of the stop spring, starting from the mechanical anchor to the free end. A continuously decreasing width may mean a continuous narrowing with a constant degree of width reduction, while a stepwise decreasing width may mean a narrowing with a piecewise continued reduction in width. The width of the stop spring can be greater in the region of the mechanical anchor than the width of the stop spring at its free end. In addition, a first width of the stop spring in a partial region of the stop spring closer to the mechanical anchor can be greater than a second width of the stop spring in a partial region closer to the free end. In other words, the stop spring becomes narrower towards its free end. According to one possible embodiment, the stop spring can become continuously narrower towards its free end without widening again.

According to the present invention, by adjusting the geometric parameters of the stop spring, the stop spring can be adapted over a wide range with regard to its mechanical properties, thus providing a high degree of design freedom with mechanical resistance that can be designed as required and adhesion behavior that can be individually optimized. For example, the stop spring can be individually designed for a provided component field of application with regard to its length, width, two-dimensional basic shape, or through material recesses or projections in the stop spring.

According to one example embodiment of the present invention, the stop spring may have a stepwise decreasing width. This can be understood as a step-by-step narrowing of the stop spring. The stop spring can have one or more steps on its outer contour, with which the width is successively reduced along the longitudinal extension of the stop spring. The steps can be formed on both sides of a central longitudinal axis of the stop spring, in particular symmetrically thereto. Depending on the embodiment, the steps along the longitudinal extension can have the same or different step heights. In this case, a step height can describe a distance between two consecutive portions of the stop spring which are offset from each other by the step. The step height can represent a measure of the corresponding reduction in width of a step. The step height can be greater than the height extension of the stop spring. A step length in the sense of a distance between two consecutive steps can vary or remain constant depending on the embodiment. With a stepwise decreasing width, the stop spring can be designed very specifically and in a geometrically simple way for increased vibration and shock resistance, for example, can be optimized with regard to its eigenmodes and its center of mass. In addition, a robust stop spring with favorable resilient spring properties is created. The stepped outer contours of the stop spring can be precisely defined, for example by photolithographic masking during a manufacturing process of the microelectromechanical component.

According to one example embodiment of the present invention, the stop spring can be in the shape of a step pyramid. This results in a regular spring shape with a stepwise decreasing width, which, due to its special geometry, is associated with a significantly improved suppression of higher oscillation modes and a reduced susceptibility to mechanical stress. In the present case, a step pyramid shape is understood to mean a two-dimensional basic shape of the stop spring with respect to its extent parallel to the substrate surface, which has an outer contour tapering towards the free end of the stop spring due to a symmetrical step arrangement and can terminate with a pyramid tip, in particular a truncated pyramid tip, at the free end. A base side of the step pyramid shape may have a shorter length than a height of the step pyramid shape along a central longitudinal axis of the stop spring. In other words, imaginary straight lines along the step edges of the step pyramid shape, which are interconnected by another straight line in the region of the mechanical anchor, can form an isosceles acute-angled triangle.

According to one example embodiment of the present invention, the stop spring can have a continuously decreasing width. In other words, the stop spring can become continuously narrower towards its free end, in particular with a constant degree of width reduction along its longitudinal extension. A straight contour course associated therewith, without step interruptions, allows for a spring shape with an optimized force flow so that the mechanical resistance of the stop spring is further increased. The stop spring can, for example, have outer contours that converge obliquely towards one another and, for example in the case of a symmetrical design of the stop spring, can form an isosceles acute-angled triangle, in particular with a truncated tip at the acute angle of the triangle. If the stop spring has a base portion and a spring portion, as explained below, the stop spring can have a continuously decreasing width at least in the spring portion.

It is possible that the stop spring has a stepwise decreasing width and a continuously decreasing width in combination, for example, starting from the mechanical anchor, it is first narrowed over a step and then has outer contours that continuously converge towards each other in the direction of the free end.

According to one example embodiment of the present invention, the stop spring can have a trapezoidal shape. This results in a regular spring shape with a continuously decreasing width, which, due to its special geometry, is associated with a significantly improved suppression of higher oscillation modes and a reduced susceptibility to mechanical stress. In the present case, a trapezoidal shape is understood to mean a two-dimensional basic shape of the stop spring with respect to its extent parallel to the substrate surface, which has two parallel sides of unequal length, here based on a longer side of the stop spring at the mechanical anchor and a shorter side of the stop spring at its free end, as well as two non-parallel legs that connect the parallel sides to each other. The trapezoidal shape can in particular be a symmetrical trapezoidal shape, i.e., it can have two non-parallel legs of equal length with equal interior angles on the parallel sides. If the stop spring has a base portion and a spring portion, as explained below, at least the spring portion of the stop spring can have a trapezoidal shape.

According to one possible embodiment of the present invention, the stop spring can have rounded corners and/or steps in order to achieve a more favorable force flow in the stop spring.

According to one example embodiment of the present invention, the stop spring can be designed as a flat stop spring with a predominantly planar extension parallel to the substrate surface. This provides the stop spring with a favorable spring elasticity, which advantageously supports the above-described mechanical resistance and the suppression of higher oscillation modes in interaction with the described two-dimensional basic shapes. In addition, improved absorption of impact energy is made possible and, due to its spring elasticity, the stop spring can exert a restoring force on a component structure that strikes the stop spring. As a flat stop spring, the stop spring has a height extension that is several times smaller than its width and length extensions. In other words, the stop spring has a much larger surface area parallel to the substrate surface than perpendicular thereto. Due to the comparatively low height extension, a low out-of-plane stiffness of the stop spring in combination with a high in-plane stiffness of the stop spring can be realized, resulting in a gentler contact load for a component structure striking the stop spring. In addition, the two-dimensional basic shape of the stop spring, which has been specifically optimized with regard to shock and vibration resistance, can be effectively used. Due to the small height extension of the stop spring and a corresponding utilization of high aspect ratios, the stop spring can be easily manufactured with a semiconductor material layer, for example a silicon-based material layer. Due to its special shaping, which is concentrated on its two-dimensional flat basic shape, the stop spring, which can be produced from a suitable material layer, for example by photolithographic processes, can also be referred to as an extruded 2D structure.

According to one example embodiment of the present invention, the stop spring can be formed axially symmetrically with respect to a central longitudinal axis of the stop spring. This makes it possible to ensure that the stop spring is evenly loaded in the event of a load, and increases the mechanical resistance of the stop spring. In addition, the mechanical behavior of the stop spring can be controlled and adjusted more precisely compared to irregular spring shapes. The central longitudinal axis, which represents a geometric central axis of the stop spring along its longitudinal extension, can extend centrally between the mechanical anchor and the free end of the stop spring.

According to one example embodiment of the present invention, the stop spring can have a through-opening. The through-opening can be a material recess in the stop spring, which connects a free space between the stop spring and the substrate with a free space between the stop spring and the movable mass, i.e., is open along a height extension of the stop spring. The through-opening can have a closed opening contour, i.e., be peripherally delimited by the material of the stop spring. The through-opening can advantageously form an etching channel between said free spaces and thus ensure an efficient etching process in the creation of the free spaces during the manufacture of the microelectromechanical component. Furthermore, the through-opening can be used for the targeted geometric structuring of the stop spring, for example in order to divide it into spring struts which build on one another hierarchically, as explained in more detail below. In principle, it is also conceivable to use the through-opening to structurally influence further mechanical properties, such as the flexural rigidity of the stop spring.

According to one example embodiment of the present invention, the through-opening can have an elongate slot shape. This advantageously allows a wide etching channel to be created without significantly impairing the stability of the stop spring. The through-opening can, for example, extend parallel to the central longitudinal axis of the stop spring and/or parallel to an outer contour of the stop spring. As a result, the elongate slot shape can be aligned substantially along the longitudinal extension of the stop spring and thus allow for favorable force flow directions in the stop spring. A through-opening with an elongate slot shape can, for example, be designed as an elongated hole with an elliptical or rectangular basic shape. In principle, other geometric basic shapes for the through-opening are also conceivable, for example square or circular through-openings.

According to one example embodiment of the present invention, the stop spring can have a plurality of through-openings, more through-openings being arranged in a first portion of the stop spring facing the mechanical anchor than in a second portion of the stop spring facing the free end of the stop spring. This achieves a favorable utilization of the surface area of the stop spring, whereby more etching channels can be provided in a generally wider portion of the stop spring to optimize etching processes, without significantly impairing the stability of the stop spring. The through-openings can, for example, be arranged next to one another and/or one after the other as seen in the longitudinal direction of the stop spring, it being possible for the number of through-openings arranged next to one another to decrease in the direction of the free end of the stop spring. For example, in the case of a stepwise decreasing width, a through-opening can be provided in a first portion starting from the free end of the stop spring, and an additional through-opening can be provided in each further portion offset from a previous portion by a further step, so that the number of through-openings arranged next to one another, for example, can increase by one or more through-openings from portion to portion in the direction of the mechanical anchor.

According to one example embodiment of the present invention, the through-openings can divide the stop spring, starting from its free end, into spring struts which build on one another hierarchically. This provides a stable yet flexible spring shape that allows for improved suppression of higher oscillation modes and reduced susceptibility to mechanical stress. The spring struts can form a tree structure. For example, the free end of the stop spring can be formed by a first spring strut, from which two further spring struts branch off in the direction of the mechanical anchor, which two further spring struts transition into three further spring struts further in the direction of the mechanical anchor. Such a division of the stop spring can be continued indefinitely. Furthermore, a more fragmented strut structure can also be formed, for example by the first spring strut branching off into three or more spring struts, from which in turn further spring struts branch off in the direction of the mechanical anchor. In this case, the through-openings can form intermediate spaces between the spring struts and space them apart from one another, for example in the width direction of the stop spring.

According to one example embodiment of the present invention, the stop spring may have a base portion on which the mechanical anchor is arranged, and a spring portion extending from the base portion to the free end of the stop spring. This allows the base portion of the stop spring to be optimized with regard to the mechanical anchor in order to ensure a stable and mechanically secure attachment of the stop spring, while the spring portion can be individually optimized with regard to spring-resilient properties and high shock and vibration resistance. The base portion may, for example, have a rectangular basic shape, while the spring portion may have a basic shape with decreasing width, for example a step pyramid shape or a trapezoidal shape.

According to one example embodiment of the present invention, the base portion may have a greater width than the spring portion. This allows for a large-area and stable mechanical anchoring to be realized, so that the stop spring is securely fixed to the substrate or to the movable mass.

According to one example embodiment of the present invention, the base portion can transition into the spring portion in a step-like manner. In this way, a first reduction in width can be implemented already in the transition between the base portion and the spring portion and, in addition, a clear functional separation can be achieved between the base portion for mechanical anchoring and the spring portion for absorbing impact energy.

According to one example embodiment of the present invention, the stop spring can be attached to the movable mass by means of the mechanical anchor. As a result, the stop spring is in particular configured for impact of the substrate against the stop spring, thereby providing a robust embodiment of the microelectromechanical component with a low sensitivity to external shock and impact effects.

According to one example embodiment of the present invention, the stop spring can be attached to the substrate by means of the mechanical anchoring. As a result, the stop spring is in particular configured for impact of the movable mass against the stop spring, whereby excessive deflections of the movable mass can be reliably limited so that mechanical overloading of the microelectromechanical component and adhesion of the movable mass to the substrate can be reliably avoided. In addition, the mass of the movable mass is not influenced by a mechanically connected stop spring, and therefore neither is its inertial behavior.

According to one example embodiment of the present invention, a stop projection can be arranged on the stop spring, on the movable mass and/or on the substrate. This creates a defined contact point at which an impact by the movable mass or the substrate can occur in a controlled manner, and a targeted introduction of force into the stop spring is possible. In addition, the stop projection reduces a contact surface between the stop spring and the substrate or the movable mass so that adhesion of the structures striking each other can be avoided or reduced. The stop projection can be arranged, for example, at the free end of the stop spring and/or in a region of the substrate or of the movable mass opposite the free end of the stop spring. If the stop projection is arranged on the stop spring, it can face the movable mass or the substrate. For example, in the case of a stop spring which is attached to the movable mass by means of the mechanical anchor, a stop projection facing the substrate can be arranged on the stop spring, or a stop projection facing the stop spring can be arranged on the substrate. For example, in the case of a stop spring which is attached to the substrate by means of the mechanical anchor, a stop projection facing the movable mass can be arranged on the stop spring, or a stop projection facing the stop spring can be arranged on the movable mass. According to one possible embodiment, a plurality of stop projections can be arranged on the stop spring, on the movable mass and/or on the substrate. These stop projections can, for example, in particular in addition to a stop projection at the free end or in a region of the substrate or the movable mass opposite the free end of the stop spring, be distributed uniformly along an outer contour of the stop spring or be concentrated in a second portion of the stop spring facing the free end, on step edges of a stop spring with a step pyramid shape.

According to one example embodiment of the present invention, the stop spring can be at the same electrical potential as the movable mass. This helps to avoid electrostatic attractive forces between the movable mass and the stop spring and, in the event of an impact, no electrical short-circuit currents occur that could cause the movable mass to weld to the stop spring. In principle, however, configurations are also conceivable in which the stop spring and the movable mass are at different electrical potentials.

According to one example embodiment of the present invention, the microelectromechanical component may comprise a plurality of stop springs arranged in a symmetrical arrangement with respect to a central axis of the substrate surface, between the substrate and the movable mass. This allows impact forces to be safely absorbed in several regions of the microelectromechanical component, and significantly increases the mechanical resistance to shock and vibration effects. A symmetrical arrangement, which can include, for example, stop springs in four corners of the substrate surface or centrally opposite one another on two sides of the substrate surface, allows for uniform loading of the stop springs. In principle, however, asymmetrical arrangements of a plurality of stop springs on the substrate surface are also conceivable, for example if, due to a predefined field of application of the microelectromechanical component, stronger force effects are to be expected in predetermined spatial directions or at predetermined spatial positions on the microelectromechanical component or on its movable mass.

According to one example embodiment of the present invention, the microelectromechanical component can be designed as a sensor component, in particular as an inertial sensor component. This allows the microelectromechanical component to be used advantageously in a mechanically demanding field of application, in which pronounced mechanical resistance as well as high shock and vibration resistance are expressly desired, and the reliability and longevity of the sensor component increase significantly. The movable mass of a microelectromechanical component designed as an inertial sensor can be designed as a seismic mass and, depending on the field of application, can be subjected to strong accelerations so that a robust sensor component can be obtained with a mechanically resistant stop structure, as provided by the described stop spring. Depending on the installation situation of the sensor component, for example in mobile devices or motor vehicles, environmental influences can also lead to significant shock effects on the microelectromechanical component so that robust and shock-resistant component structures, such as those attainable with the described stop spring, can contribute to fail-safe operation of the sensor component. As an inertial sensor component, the microelectromechanical component can be configured to detect rotational and/or translational accelerations and can be implemented, for example, in an acceleration sensor, rotation rate sensor or an inertial measurement unit (IMU) with a plurality of inertial sensors. The inertial sensor component can in particular be configured for direction-dependent acceleration detection. The inertial sensor component can be configured as a so-called out-of-plane sensor component or z-sensor component, in particular for detecting accelerations perpendicular to the substrate surface. Depending on the acceleration force to be detected and the measurement principle used, the seismic mass can, for example, be designed as a rocker structure with rocker arms that have an asymmetric mass distribution and are pivotable about a torsion spring axis; it can be designed as a trampoline structure with a translational displaceability of the entire seismic mass, or it can be configured as an oscillating rotor for rotation rate detection. Especially in microelectromechanical sensor components designed as inertial sensor components, stop springs represent an important mechanical protective element as flexible stoppers for the seismic mass. They serve as the resilient first contact point of the seismic mass in the case of accelerations that exceed a predefined acceleration threshold value for acceleration detection, and thus avoid mechanical overload on the microelectromechanical component structures.

The present invention also relates to a microelectromechanical inertial sensor having a microelectromechanical component according to one of the above-described features and having a signal processing unit for applying, receiving and/or processing signals of the microelectromechanical component. The microelectromechanical inertial sensor of the present invention can also achieve the above-described advantages of increased mechanical robustness and improved shock and vibration resistance with regard to the microelectromechanical component. For this purpose, the microelectromechanical component can be designed as an inertial sensor component. The inertial sensor can be configured to detect rotational and/or translational accelerations. The inertial sensor can in particular be configured for direction-dependent acceleration detection. Optionally, the inertial sensor can be implemented in combination with further inertial sensors in an inertial measurement unit. The signal processing unit of the inertial sensor can be understood as a control circuit, which can be designed in particular as an integrated circuit, for example as an ASIC (application-specific integrated circuit). The signal processing unit can, for example, be used to receive and evaluate measurement signals of the microelectromechanical component and to perform control tasks.

According to one example embodiment of the present invention, the microelectromechanical inertial sensor can be designed as a z-acceleration sensor. Such acceleration sensors are also called out-of-plane acceleration sensors and are configured to detect a deflection of the movable mass of the microelectromechanical component perpendicular to the substrate surface. Z-acceleration sensors can be configured in particular to detect translational accelerations. For z-acceleration sensors in which the movable mass can be deflected towards the substrate, for example, the advantages of a robust stop spring as described for the microelectromechanical component described above can contribute to an overall increased mechanical resistance and longevity of the z-acceleration sensor.

According to an alternative embodiment of the present invention, the microelectromechanical inertial sensor can be designed as a rotation rate sensor. Rotation rate sensors are also called gyroscopes and are configured to detect rotational accelerations of the movable mass of the microelectromechanical component, which can be designed for this purpose as a rotor, for example. With regard to rotation rate sensors, the advantages of a robust stop spring as described for the microelectromechanical component described above can also contribute to an overall increased mechanical resistance and longevity of the rotation rate sensor.

The above-described microelectromechanical component and/or the above-described microelectromechanical inertial sensor can advantageously be used in connection with at least one of the following fields of application: smartphones and tablets, wearables, hearables, AR and VR, drones, games and toys, robots, smart home. Implementation is also conceivable in an industrial context for the following applications and functions, for example: wake-up function for selected device modules, screen and device orientation, detection of significant movements, shocks and free falls; HMI functionality, e.g., multi-tap detection; activity, gesture and context recognition; feature personalization; motion control, balance, gimbal, altitude stabilization, flight control, image stabilization, indoor and outdoor navigation, floor detection, position tracking, PDR (pedestrian dead reckoning), boundary and congestion detection, dynamic path planning, indoor SLAM (simultaneous localization and map creation) ; intrusion monitoring, real-time motion detection and tracking, activity tracking, step counting, calorie counting, sleep monitoring; in-ear detection, head movement detection; object tracking, energy management and power-saving sensing, predictive maintenance; precise sensor data fusion.

In general, in the context of this application, the words “a/an,” unless expressly defined otherwise, are not to be understood as numerals, but as indefinite articles with the literal meaning of “at least one.”

The present invention allows for various embodiments and is explained in more detail below using exemplary embodiments with the figures.

### BRIEF DESCRIPTION OF THE DRAWINGS

FIG. 1 is a front view of a microelectromechanical component according to a first embodiment of the present invention with a stop spring according to a first exemplary embodiment of the present invention.

FIG. 2 is a perspective plan view of the microelectromechanical component according to FIG. 1, with a movable mass of the microelectromechanical component hidden.

FIG. 3 is an isolated representation of the stop spring according to the first exemplary embodiment in a plan view.

FIG. 4 is an isolated representation of the stop spring according to the first exemplary embodiment in a perspective plan view.

FIGS. 5 and 6 are schematic illustrations of load conditions of the stop spring according to the first exemplary embodiment in a perspective plan view.

FIG. 7 is a front view of a microelectromechanical component according to a second embodiment with a stop spring according to the first exemplary embodiment.

FIG. 8 is a perspective plan view of the microelectromechanical component according to FIG. 7, with a movable mass of the microelectromechanical component hidden.

FIG. 9 is an isolated representation of a stop spring according to a second exemplary embodiment of the present invention in a plan view.

FIG. 10 is an isolated representation of the stop spring according to the second exemplary embodiment in a perspective plan view.

FIG. 11 is a sectional plan view of a microelectromechanical component with two stop springs, according to an example embodiment of the present invention.

FIG. 12 is a schematic diagram of a microelectromechanical inertial sensor, according to an example embodiment of the present invention.

### DETAILED DESCRIPTION OF EXAMPLE EMBODIMENTS

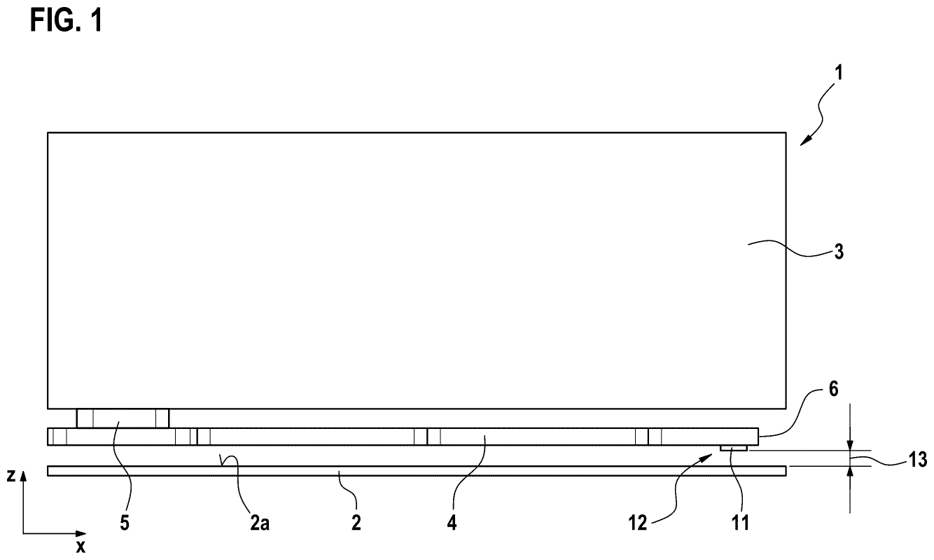

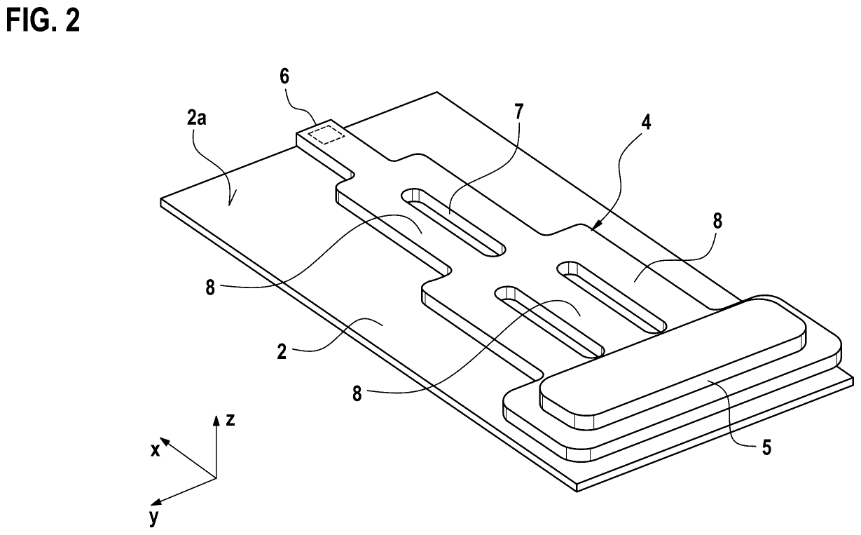

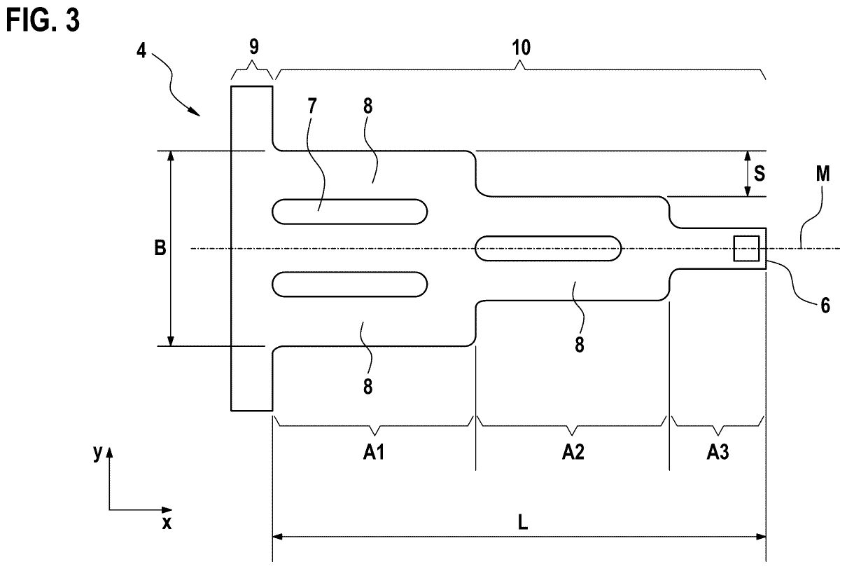

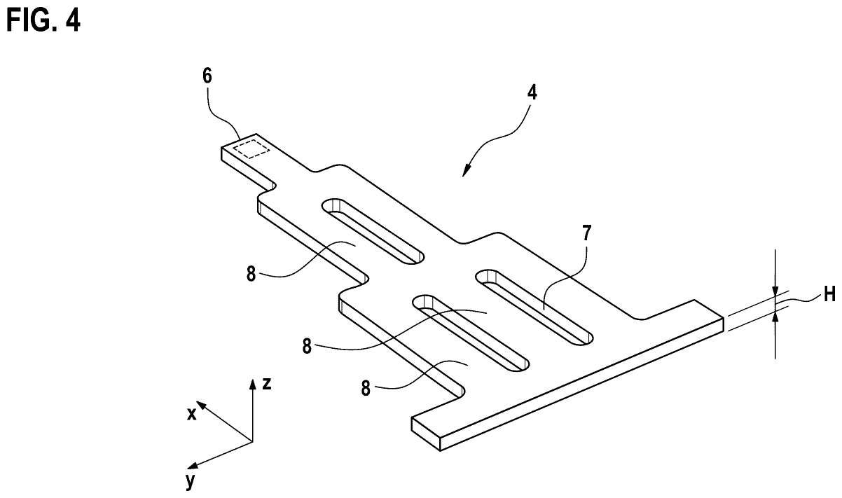

FIGS. 1 and 2 show a microelectromechanical component 1 according to a first embodiment with a stop spring 4 according to a first exemplary embodiment. FIGS. 3 and 4 additionally show an isolated representation of the stop spring 4 according to the first exemplary embodiment. The microelectromechanical component 1 can be designed as a sensor component, in particular as an inertial sensor component. The microelectromechanical component 1 can be manufactured using semiconductor technology by successive arrangement and structuring of material layers, in particular silicon-based material layers.

The microelectromechanical component 1 comprises a substrate 2 having a substrate surface 3. The substrate 2 can be a silicon wafer, for example. The substrate surface 2a can form an active front side of the silicon wafer. The microelectromechanical component 1 further comprises a mass 3 that is movable relative to the substrate surface 2a. The movable mass 3 is deflectable in particular perpendicularly to the substrate surface 2a and can be designed as a seismic mass if the microelectromechanical component 1 is designed as an inertial sensor component. The movable mass 3 can be attached, for example, to a frame (not shown in more detail) and/or to the substrate 2 of the microelectromechanical component 1 via a spring structure (not shown in more detail).

As can be seen in FIG. 1, the microelectromechanical component 1 has a stop spring 4 arranged between the substrate 2 and the movable mass 3. The stop spring 4 is a resiliently deflectable mechanical protective element of the microelectromechanical component 1 and serves to absorb impact energy of the substrate 2 which is accelerated, for example, by an impact on the stop spring 4. According to the first embodiment of the microelectromechanical component 1, the stop spring 4 is attached to the movable mass 3 by means of a mechanical anchor 5. As a result, the stop spring 4 is configured for impact of the substrate 2 against the stop spring 4 in order to realize a robust design of the microelectromechanical component 1 with a low sensitivity to shock and impact effects. The stop spring 4 extends from the mechanical anchor 5, at least in an unloaded rest state, in a cantilevered manner parallel to the substrate surface 2a. The free spaces shown in FIG. 1 between the substrate 2 and the stop spring 4 as well as between the stop spring 4 and the movable mass 3 can be created in particular by selective etching processes. The free space located between the stop spring 4 and the substrate 2 and facing a free end 6 of the stop spring 4 is referred to as the contact region 12.

It can be seen in FIGS. 3 and 4 that the stop spring 4 has a longitudinal extension L along a first spatial axis x, a width extension B along a second spatial axis y, and a height extension H along a third spatial axis z. The first spatial axis x and the second spatial axis y can span a spatial plane parallel to the substrate surface 2, while the third spatial axis z can run perpendicularly to the substrate surface 2. For example, it can be seen in FIG. 3 that the stop spring 4 has a decreasing width B along its longitudinal extension L starting from the mechanical anchor 5 to the free end 6 of the stop spring 4. The stop spring 4 therefore becomes narrower towards its free end 6. This creates a robust stop spring 4 with a reduced susceptibility to adhesion of an impacting component structure, which also has an improved suppression of higher oscillation modes and increased vibration and shock resistance. The microelectromechanical component 1 can thus be protected efficiently and reliably in a simple manner against mechanical overload, in a compact design.

According to the first exemplary embodiment of the stop spring 4 shown in FIG. 1 to 4, the stop spring has a stepwise decreasing width B so that a successive abrupt reduction in width is achieved. In particular, the stop spring 4 can have a plurality of steps on its outer contour, with each of which a step-by-step width reduction can be achieved depending on a step height S, starting from a first portion Al, which faces the mechanical anchor 5, via a second portion A2, which faces the free end 6, to a third portion A3, which terminates with the free end 6. In principle, the number of steps can be increased or decreased in any way. As can be seen in FIG. 4, the step height S shown in FIG. 3 can be greater than a height extension H of the stop spring marked in FIG. 4.

According to the first exemplary embodiment shown in FIG. 2 to 4, the stop spring 4 has a step pyramid shape. This shape forms a two-dimensional basic shape of the stop spring 4. Accordingly, the stop spring 4 has a regular spring shape with a stepwise decreasing width and a symmetrical step arrangement. In this case, the step pyramid shape can have a truncated pyramid tip so that a straight free end 6 with a defined width extension B is formed. The step pyramid shape allows for significantly improved suppression of higher oscillation modes and reduced susceptibility to mechanical stress. Furthermore, it can be seen in FIG. 3 that the stop spring 4 is axially symmetrical with respect to a central longitudinal axis M of the stop spring 4 so that a uniform mechanical loading capacity of the stop spring 4 is achieved.

In FIGS. 1, 2 and 4, it can be seen that the stop spring 4 is designed as a flat stop spring 4 with a predominantly planar extension parallel to the substrate surface 2a. The stop spring 4 therefore has, as can be seen in FIG. 4, a significantly smaller height extension H than width extension B and longitudinal extension L. This provides a stop spring 4 with a high in-plane stiffness, a low out-of-plane stiffness and with spring properties favorable for resilient energy absorption, in which the two-dimensional basic shape is structurally in the foreground and is specifically optimized for setting the desired mechanical properties of the stop spring 4.

As shown in FIG. 1, a stop projection 11 can be arranged on the stop spring 4. In an unloaded rest state of the stop spring 4, there is a defined rest distance 13 between the stop projection 11 and the substrate 2. When the stop spring 4 is loaded, a targeted and controlled force is introduced into the stop spring 4 via the stop projection 11. In principle, it is conceivable to arrange a plurality of stop projections 11 on the stop spring 4, on the substrate 2 and/or on the movable mass 3.

It can be seen in FIG. 2 to 4 that the stop spring 4 has a plurality of through-openings 7. These through-openings serve in particular as etching channels in the microelectromechanical component 1 during its manufacture but can also allow for a targeted geometric structuring of the stop spring 4 and an influence on mechanical properties such as a flexural rigidity of the stop spring 4. According to the design option shown, the through-openings 7 have an elongate slot shape and extend parallel to the central longitudinal axis M of the stop spring 4 so that wide etching channels are created, but a stable basic Structure of the stop spring 4 is still maintained with efficient surface area utilization.

In FIG. 3, it can be seen that, in a first portion Al of the stop spring 4 facing the mechanical anchor 5, there are more through-openings 7, here two through-openings 7 by way of example, than in a second portion A2 of the stop spring 4 facing the free end 6 of the stop spring 4, in which second portion one through-opening 7 is positioned as shown. The through-openings 7 of the first portion Al are arranged next to each other. The through-openings 7 of the first portion A1 and of the second portion A2 are arranged successively along the longitudinal extension L of the stop spring 4.

Through the through-openings 7, the stop spring 4 is divided into spring struts 8 which build on one another hierarchically, as can be seen in FIG. 2 to 4, whereby a stable yet flexible spring shape is provided, with which an improved suppression of higher oscillation modes and a reduced susceptibility to mechanical stress can be achieved. As can be seen, for example, in FIG. 3, the spring struts 8 can form a tree structure in that additional spring struts 8 branch off from one another, starting from the free end 6 to the mechanical anchor 5 of the stop spring 4.

In FIG. 3, it is further illustrated that the stop spring 4 has a base portion 9 on which the mechanical anchor 5 is arranged, as can be seen, for example, in FIG. 2. Starting from the base portion 9, a spring portion 10 extends to the free end 6 of the stop spring 4. As shown in FIG. 3, the base portion 9 has a greater width B than the spring portion 10. As a result, the stop spring 4 can be optimized in portions with regard to a stable mechanical anchor 5 and its spring and stop function in the spring portion 10. The base portion 9 transitions in a step-like manner into the spring portion 10 so that a clear separation of functions and first reduction in width can be realized in this transition.

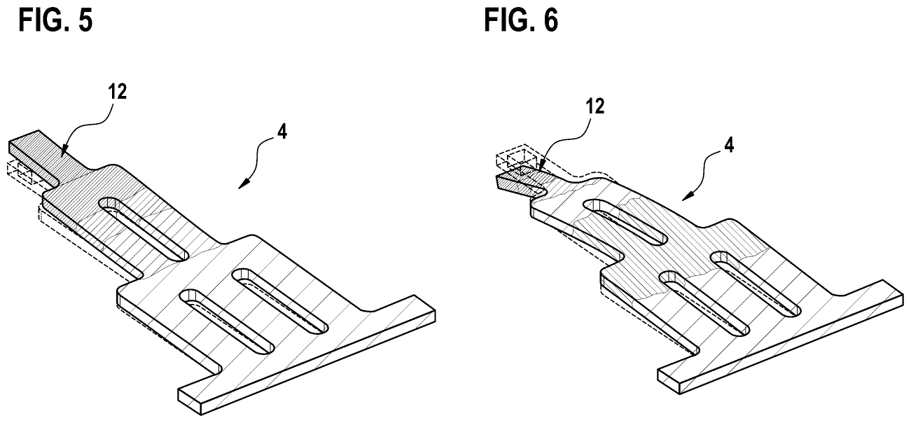

FIGS. 5 and 6 show load conditions, by way of example, of the stop spring 4 according to the first exemplary embodiment, such as can occur, for example, in the case of a simulated shock situation on the microelectromechanical component 1. As can be seen in FIGS. 5 and 6, when the stop spring 4 is contacted in its contact region 12, the free end 6 is deflected and the stop spring 4 is elastically deformed to convert impact energy. Due to the special spring shape, a very low-stress deformation response of the stop spring 4 results in this case, with a curved course of the stop spring 4, so that the stop spring is characterized by a high shock and vibration resistance with favorable spring and restoring forces.

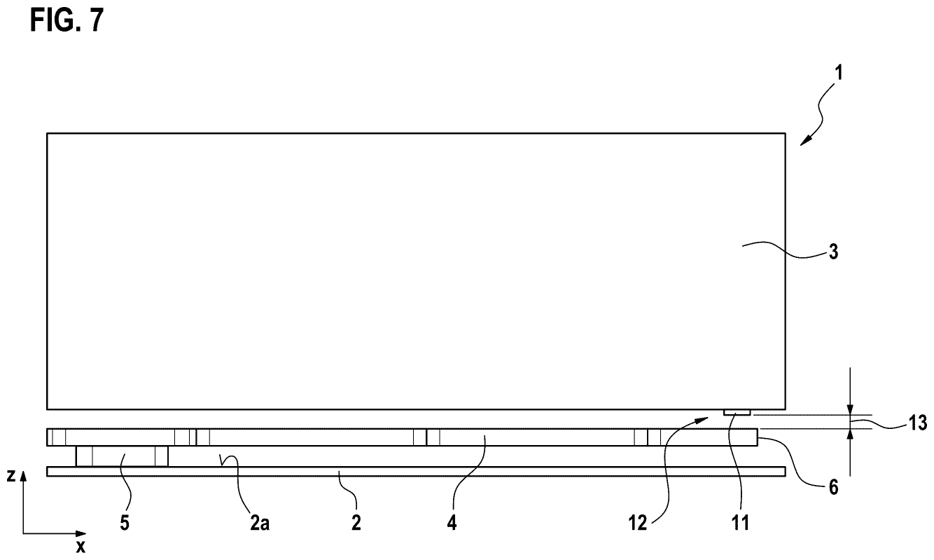

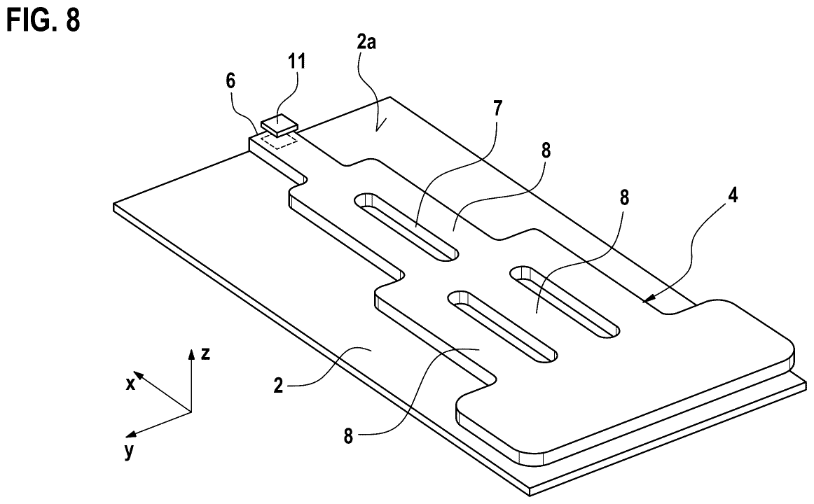

FIGS. 7 and 8 show a microelectromechanical component 1 according to a second embodiment with a stop spring 4 according to the first exemplary embodiment. The microelectromechanical component 1 according to the second embodiment is comparable to the microelectromechanical component 1 according to the first embodiment with regard to its basic structure and general functioning. As can be seen in FIG. 7, the microelectromechanical component 1 here also has a stop spring 4 arranged between the substrate 2 and the movable mass 3.

However, according to the second embodiment of the microelectromechanical component 1, the stop spring 4 is attached to the substrate 2 by means of a mechanical anchor 5. As a result, the stop spring 4 is configured for impact of the movable mass 3 against the stop spring 4 so that the movable mass 3 can be reliably stopped in the event of excessive deflection. In addition, the movable mass 3 remains unaffected by the stop spring 4 with regard to its inertial behavior.

The stop spring 4 extends from the mechanical anchor 5 in a cantilevered manner parallel to the substrate surface 2a. In addition, as shown in FIG. 7, a stop projection 11 is arranged on the movable mass 3. In an unloaded rest state of the stop spring 4, there is a defined rest distance 13 between the stop projection 11 and the stop spring 4. The contact region 12 is located here between the stop spring 4 and the movable mass 3 in a region facing the free end 6 of the stop spring 4.

It is not shown in more detail but is advantageous if the stop spring 4 is at the same electrical potential as the movable mass 3 in order to avoid electrostatic attractive forces between the movable mass 3 and the stop spring 4 and thus reduce the risk of adhesion between the two component structures.

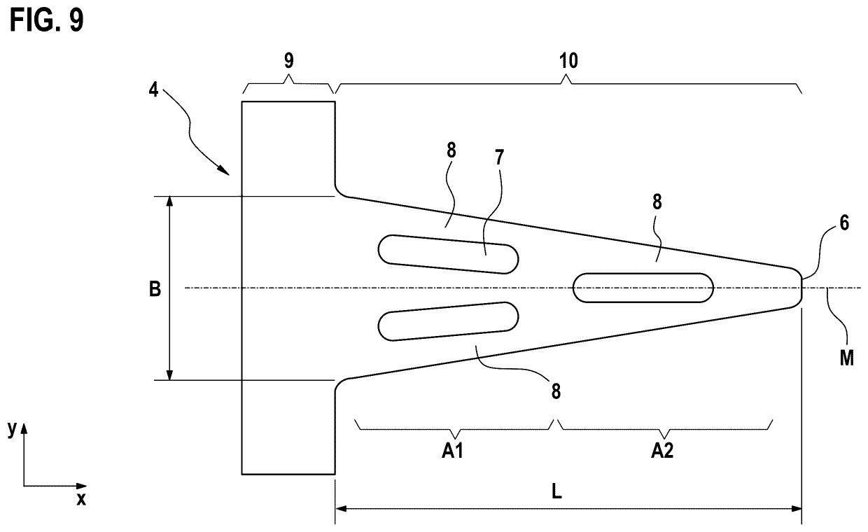

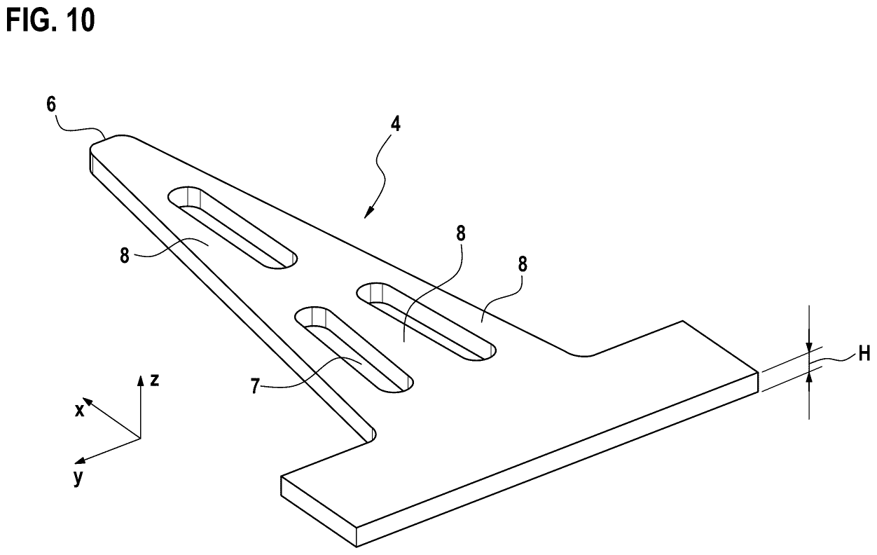

FIGS. 9 and 10 show an isolated representation of a stop spring 4 according to a second exemplary embodiment. In its basic structure and general functioning, the stop spring 4 according to the second exemplary embodiment is comparable to the stop spring 4 according to the first exemplary embodiment. Thus, the stop spring 4 according to the second exemplary embodiment also has, for instance, a base portion 9 and a spring portion 10 which is offset therefrom in a stepwise manner, as well as through-openings 7 which divide the stop spring 4 into spring struts 8 which build on one another hierarchically. In addition, the stop spring 4 according to the second exemplary embodiment is designed as a flat stop spring 4 and axially symmetrical with respect to its central longitudinal axis M. In contrast to the stop spring 4 according to the first exemplary embodiment, the stop spring 4 according to the second exemplary embodiment has a continuously decreasing width B along the spring portion 10, whereby an optimized force flow along the outer contour of the stop spring 4 can be achieved. In the second exemplary embodiment, the spring portion 10 has a trapezoidal shape, which is symmetrical in the present case. The trapezoidal shape makes it possible to achieve significantly improved suppression of higher oscillation modes and reduced susceptibility to mechanical stress.

For the stop spring 4, there is fundamentally a high degree of design freedom with individually adjustable geometric parameters so that the mechanical resistance desired for a particular field of application can be adjusted and optimized over a wide range.

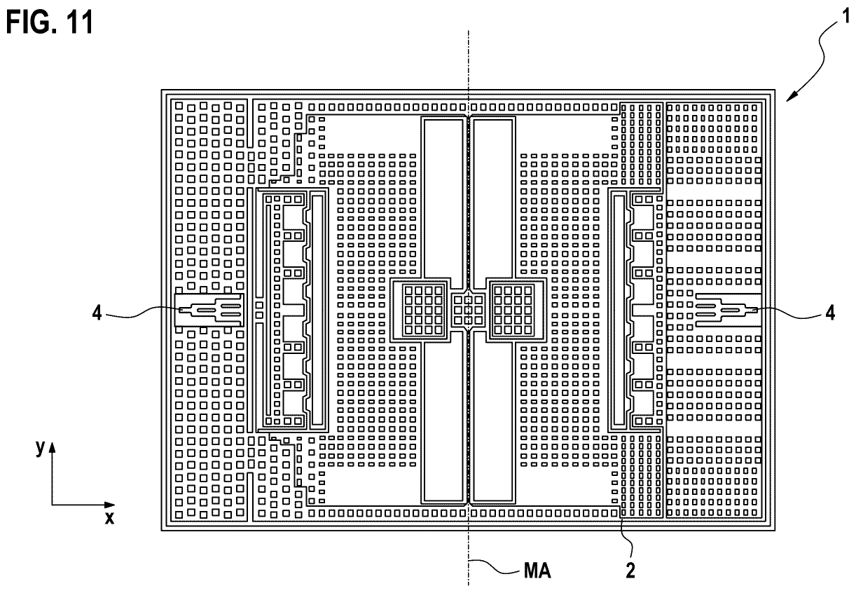

FIG. 11 shows a microelectromechanical component 1 with two stop springs 4. The stop springs 4 are arranged symmetrically with respect to a central axis MA of the substrate surface 2a, between the substrate 2 and the movable mass 3 so that impact forces can be reliably absorbed in several regions of the microelectromechanical component 1 and the mechanical resistance of the microelectromechanical component 1 is increased overall. According to the exemplary embodiment shown, the microelectromechanical component 1 is designed as an inertial sensor component and is configured to detect out-of-plane accelerations perpendicular to the substrate surface 2a.

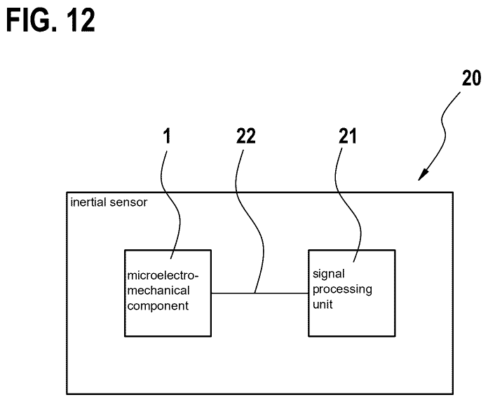

FIG. 12 shows a simplified schematic diagram of a microelectromechanical inertial sensor 20 with a microelectromechanical component 1. The microelectromechanical inertial sensor can be designed, for example, as a z-acceleration sensor or as a rotation rate sensor. The microelectromechanical component 1 is designed as an inertial sensor component. The microelectromechanical inertial sensor 20 has a signal processing unit 21, designed for example as an ASIC, for applying, receiving and/or processing signals of the microelectromechanical component 1, which is connected by signal technology to the microelectromechanical component 1 via a signal connection 22, for example one or more wire bond connections. The microelectromechanical inertial sensor 20 is characterized by increased mechanical resistance and improved shock and vibration resistance due to the microelectromechanical component 1 optimized as described above. The microelectromechanical inertial sensor 20 is therefore robust, durable and suitable for providing precise measurement signals even in more demanding application environments.

1-23. (canceled)

24. A microelectromechanical component, comprising:
a substrate with a substrate surface;
a moveable mass that is movable relative to the substrate surface; and
a stop spring arranged between the substrate and the movable mass;
wherein the stop spring extends from a mechanical anchor in a cantilevered manner parallel to the substrate surface, and
wherein the stop spring has a decreasing width along a longitudinal extension of the stop spring from the mechanical anchor to a free end of the stop spring.

25. The microelectromechanical component according to claim 24, wherein the stop spring has a width that decreases in a stepwise manner.

26. The microelectromechanical component according to claim 25, wherein the stop spring has a step pyramid shape.

27. The microelectromechanical component according to claim 24, wherein the stop spring has a continuously decreasing width.

28. The microelectromechanical component according to claim 27, wherein the stop spring has a trapezoidal shape.

29. The microelectromechanical component according to claim 24, wherein the stop spring is a flat stop spring with a predominantly planar extension parallel to the substrate surface.

30. The microelectromechanical component according to claim 24, wherein the stop spring is axially symmetrical with respect to a central longitudinal axis of the stop spring.

31. The microelectromechanical component according to claim 24, wherein the stop spring has a through-opening.

32. The microelectromechanical component according to claim 31, wherein the through-opening has an elongate slot shape.

33. The microelectromechanical component according to claim 24, wherein the stop spring has a plurality of through-openings, and wherein more through-openings are arranged in a first portion of the stop spring facing the mechanical anchor than in a second portion of the stop spring facing the free end of the stop spring.

34. The microelectromechanical component according to claim 33, wherein the through-openings divide the stop spring, starting from the free end, into spring struts which build on one another hierarchically.

35. The microelectromechanical component according to claim 24, wherein the stop spring has a base portion on which the mechanical anchor is arranged, and a spring portion extending from the base portion to the free end of the stop spring.

36. The microelectromechanical component according to claim 35, wherein the base portion has a greater width than the spring portion.

37. The microelectromechanical component according to claim 35, wherein the base portion transitions in a step-like manner into the spring portion.

38. The microelectromechanical component according to claim 24, wherein the stop spring is attached to the movable mass by the mechanical anchor.

39. The microelectromechanical component according to claim 24, wherein the stop spring is attached to the substrate by the mechanical anchor.

40. The microelectromechanical component according to claim 24, wherein a stop projection is arranged on the stop spring and/or on the movable mass and/or on the substrate.

41. The microelectromechanical component according to claim 24, wherein the stop spring is at a same electrical potential as the movable mass.

42. The microelectromechanical component according to claim 24, wherein the microelectromechanical component has a plurality of stop springs arranged in a symmetrical arrangement with respect to a central axis of the substrate surface between the substrate and the movable mass.

43. The microelectromechanical component according to claim 24, wherein the microelectromechanical component is an inertial sensor component.

44. A microelectromechanical inertial sensor, comprising:
a microelectromechanical component including:
a substrate with a substrate surface,
a moveable mass that is movable relative to the substrate surface, and
a stop spring arranged between the substrate and the movable mass,
wherein the stop spring extends from a mechanical anchor in a cantilevered manner parallel to the substrate surface, and
wherein the stop spring has a decreasing width along a longitudinal extension of the stop spring from the mechanical anchor to a free end of the stop spring; and
a signal processing unit configured to apply and/or receive and/or processing signals of the microelectromechanical component.

45. The microelectromechanical inertial sensor according to claim 44, wherein the microelectromechanical inertial sensor is a z-acceleration sensor.

46. The microelectromechanical inertial sensor according to claim 44, wherein the microelectromechanical inertial sensor is a rotation rate sensor.
